(19) United States
(12) Patent Application Publication
(10) Pub. No.: US 2015/0194314 A1
(43) Pub. Date: Jul. 9, 2015

(54) SEMICONDUCTOR DEVICE AND METHOD OF FABRICATING THE SAME

(71) Applicant: MACRONIX International Co., Ltd., Hsinchu (TW)

(72) Inventors: Ta-Kang Chu, Hsinchu (TW); Hung-Chi Chen, Hsinchu (TW); Cheng-Ming Yih, Hsinchu (TW)

(73) Assignee: MACRONIX International Co., Ltd., Hsinchu (TW)

(21) Appl. No.: 14/278,953

(22) Filed: May 15, 2014

(30) Foreign Application Priority Data
Jan. 9, 2014 (TW) 103100832

(51) Int. Cl. H01L 21/283; H01L 29/78; H01L 29/417; H01L 21/02

(52) U.S. Cl. CPC H01L 21/283; H01L 21/022; H01L 29/78; H01L 29/41775

(57) ABSTRACT

A method of fabricating a semiconductor device is provided. A substrate having a first region and a second region is provided. A plurality of stacked gate structures are formed on the substrate of the first region. Each stacked gate structure includes a tunneling dielectric layer, a charge storage layer, an inter-gate dielectric layer, and a control gate. A gap exists between two adjacent stacked gate structures. At least one gate structure is formed on the substrate of the second region. A liner layer is conformally formed on the substrate. A dielectric layer covering the liner layer is formed in the second region. A metal silicide layer is formed on the top portion of the gate structure and on the substrate on both sides of the gate structure. A contact process is performed to form a plurality of contacts connected to the metal silicide layer.

### CROSS-REFERENCE TO RELATED APPLICATION

This application claims the priority benefit of Taiwan application serial no. 103100832, filed on Jan. 9, 2014. The entirety of the above-mentioned patent application is hereby incorporated by reference herein and made a part of this specification.

### BACKGROUND OF THE INVENTION

1. Field of the Invention

The invention is related to a semiconductor device and a method of fabricating the same, and more particularly, to a memory and a method of fabricating the same.

2. Description of Related Art

In general, with the decrease in size of the memory, a self-aligned contact (SAC) process is applied to overcome the increasingly shrinking wire width and to avoid misalignment of contacts.

However, how to effectively integrate the SAC process in the memory cell region and the metal silicide process in the peripheral circuit region has become an urgent topic that needs to be solved.

### SUMMARY OF THE INVENTION

The invention provides a method of fabricating a semiconductor device. The method can integrate a SAC process and a self-aligned metal silicide process and fabricate a semiconductor device having a metal silicide layer in the peripheral circuit region.

The method of fabricating a semiconductor device of the invention includes the following steps. A substrate having a first region and a second region is provided, wherein a plurality of stacked gate structures are formed on the substrate of the first region, each stacked gate structure includes a tunneling dielectric layer, a charge storage layer, an inter-gate dielectric layer, and a control gate, a gap exists between two adjacent stacked gate structures, and at least one gate structure is formed on the substrate of the second region. A liner layer is conformally formed on the substrate. A dielectric layer covering the liner layer is formed in the second region. A metal silicide layer is formed on the top portion of the gate structure and on the substrate on both sides of the gate structure. A contact process is performed to form a plurality of contacts connected to the metal silicide layer.

In an embodiment of the invention, the liner layer includes a multilayer structure of a silicon oxide layer/a silicon nitride layer/a silicon oxide layer (ONO).

In an embodiment of the invention, the following steps are further included before the metal silicide layer is formed on the top portion of the gate structure and on the substrate on both sides of the gate structure. A portion of each of the dielectric layer and the liner layer is removed to form a spacer and a plurality of openings on the substrate.

The semiconductor device of the invention includes a substrate, a plurality of stacked gate structures, a liner layer, at least one gate structure, a metal silicide layer, and a plurality of contacts. The substrate has a first region and a second region. The stacked gate structures are disposed on the substrate of the first region, wherein each stacked gate structure includes a tunneling dielectric layer, a charge storage layer, a blocking dielectric layer, and a control gate, and a gap exists between two adjacent stacked gate structures. The liner layer is disposed on the sidewall of each stacked gate structure. The gate structure is disposed on the substrate of the second region. The metal silicide layer is disposed on the top portion of the gate structure and on the substrate on both sides of the gate structure. The contacts are connected to the metal silicide layer.

In an embodiment of the invention, the liner layer includes a multilayer structure of a silicon oxide layer/a silicon nitride layer/a silicon oxide layer (ONO).

In an embodiment of the invention, the semiconductor device further includes an interlayer dielectric layer disposed on the substrate of the second region and covering the gate structure, wherein the interlayer dielectric layer has a plurality of contact holes therein.

The semiconductor device of the invention includes a substrate, a plurality of first gate structures, a liner layer, at least one second gate structure, and a plurality of contacts. The substrate has a first region and a second region. The first gate structures are disposed on the substrate of the first region, wherein each first gate structure includes a tunneling dielectric layer, a charge storage layer, an inter-gate dielectric layer, and a control gate, and a gap exists between two adjacent stacked gate structures. The liner layer is disposed on the sidewall of each first gate structure. The second gate structure is disposed on the substrate of the second region. The contacts are connected to the top portion of the second gate structure and the substrate on both sides of the second gate structure.

In an embodiment of the invention, the semiconductor device further includes a metal silicide layer disposed on the top portion of the second gate structure and on the substrate on both sides of the second gate structure.

In an embodiment of the invention, the control gate of the first gate structure located at the junction of the first region and the second region has a stepped shape.

In an embodiment of the invention, the liner layer includes a multilayer structure of a silicon oxide layer/a silicon nitride layer/a silicon oxide layer (ONO).

Based on the above, the method of fabricating a semiconductor device provided by the invention can integrate a SAC process and a self-aligned metal silicide process to fabricate a semiconductor device having a SAC in the first region and a metal silicide layer in the second region.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1N are cross-sectional views illustrating the process of a method of fabricating a semiconductor device according to an embodiment of the invention.

### DESCRIPTION OF THE EMBODIMENTS

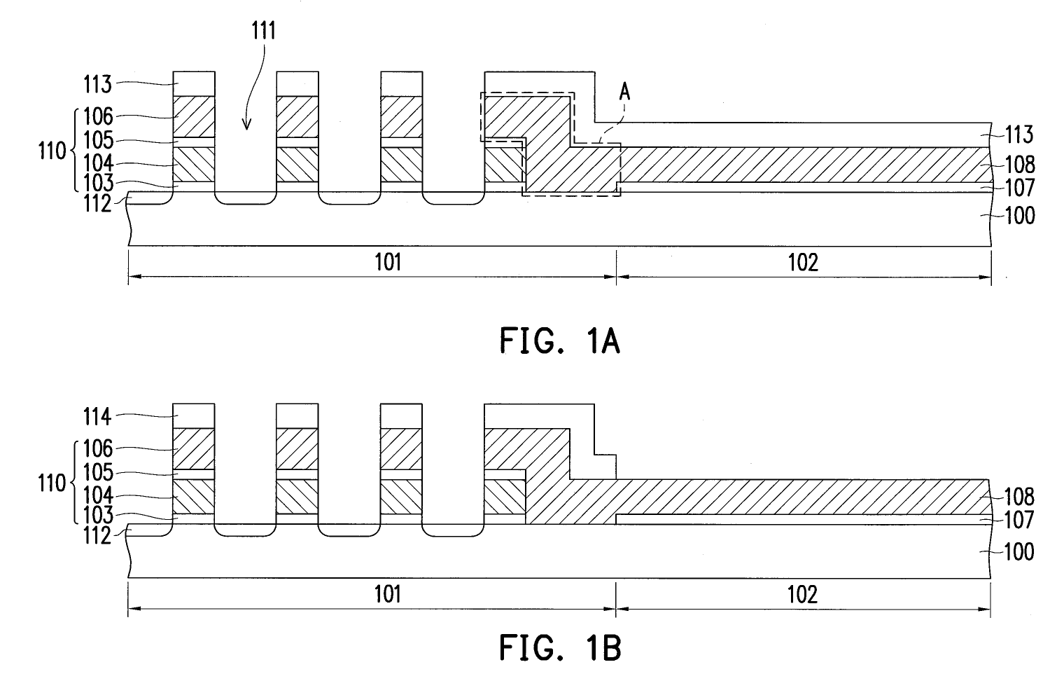

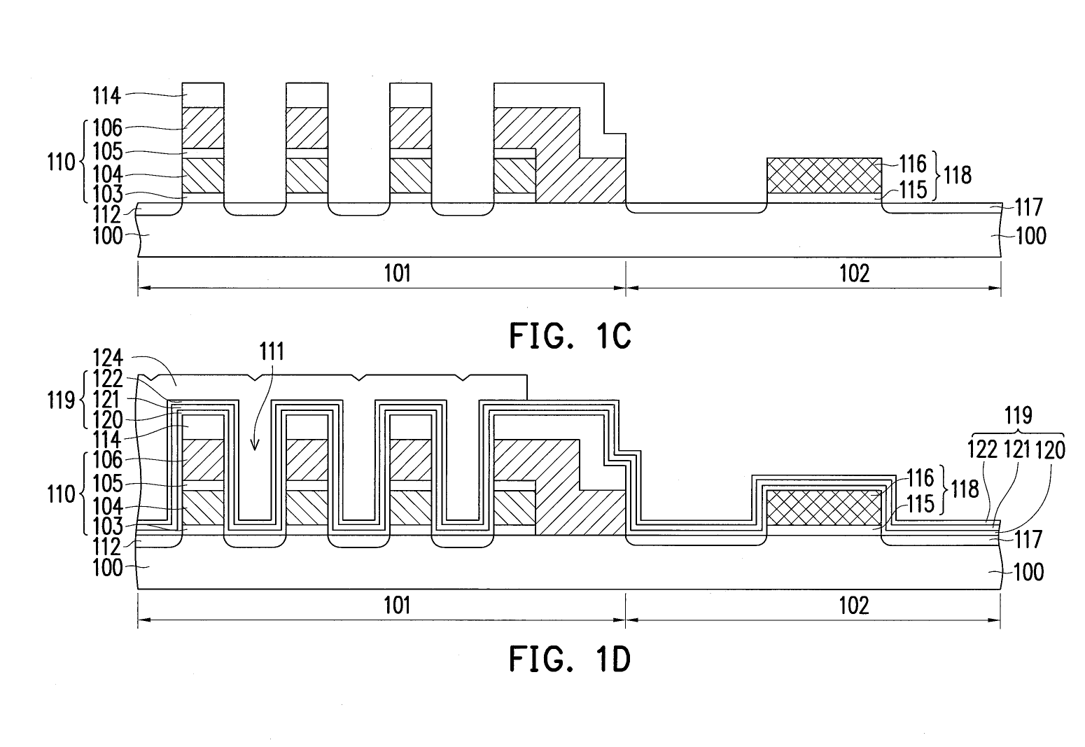

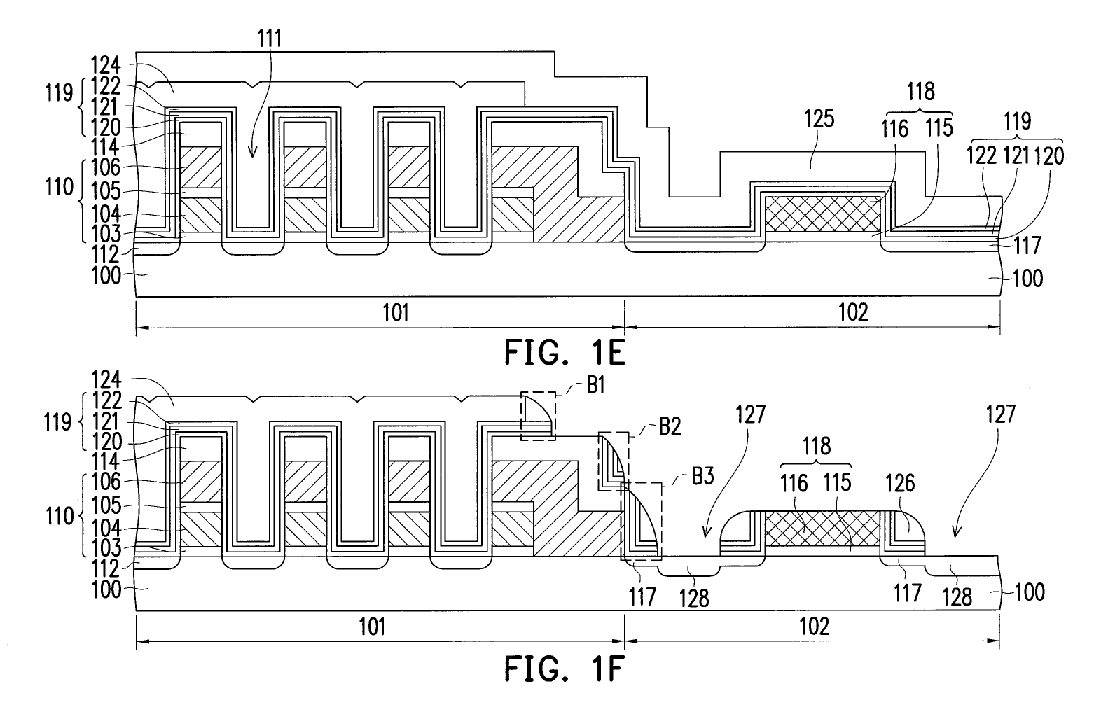

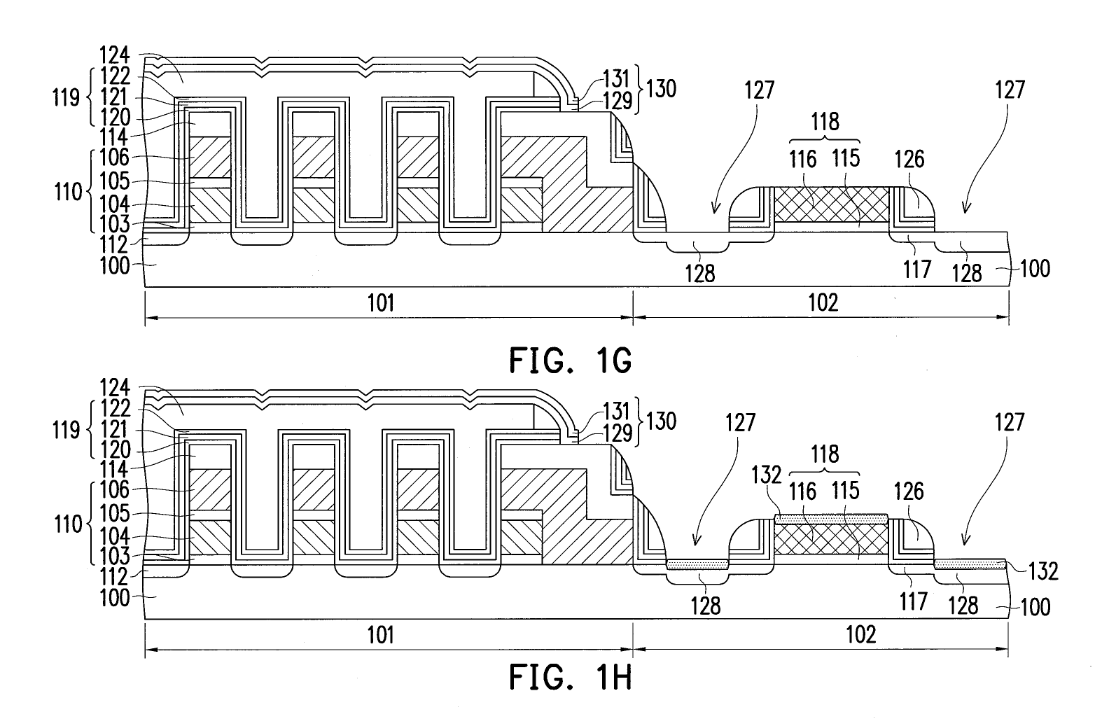

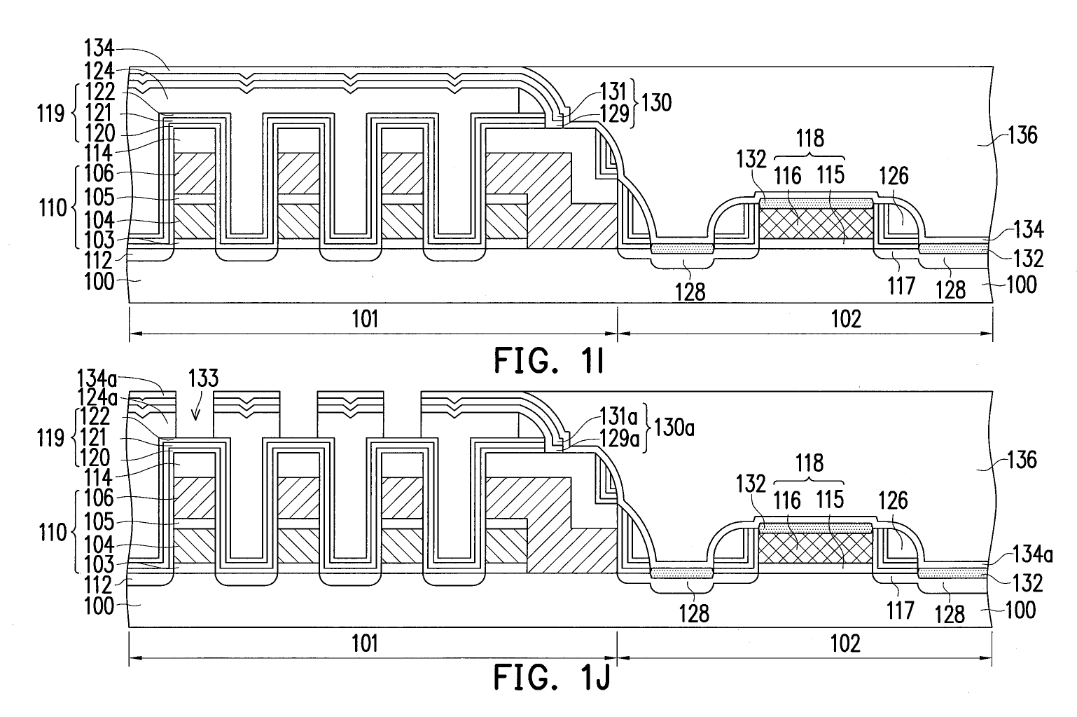

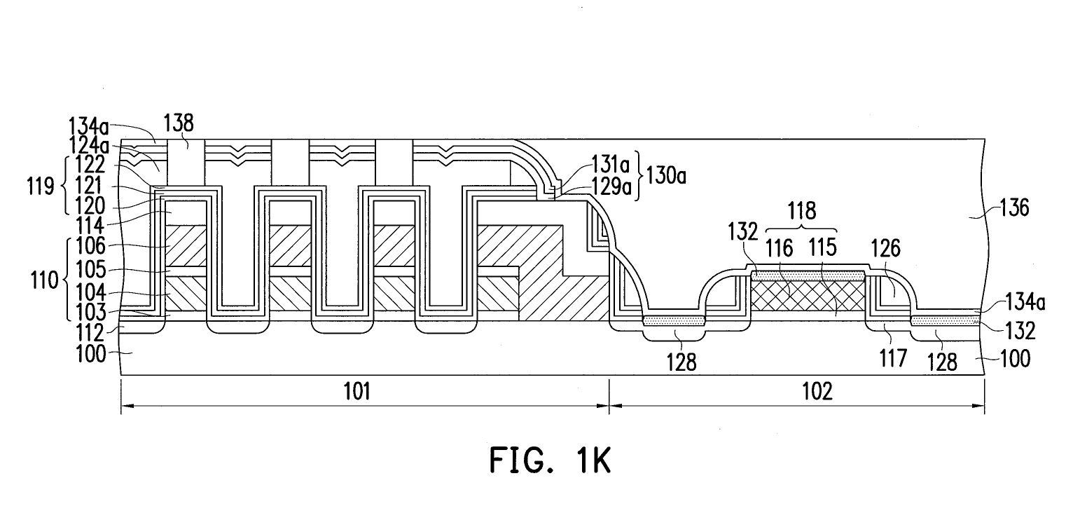

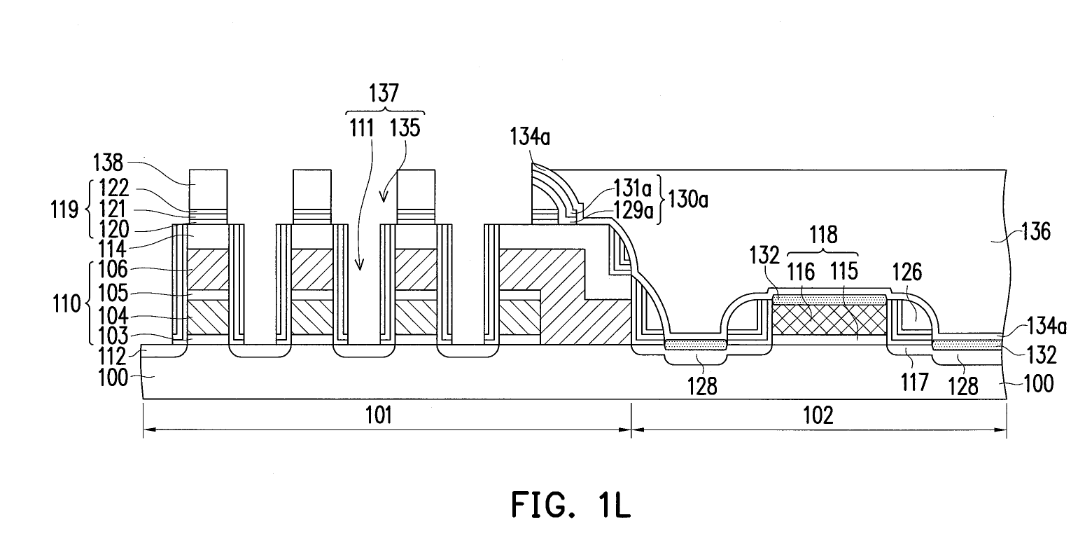

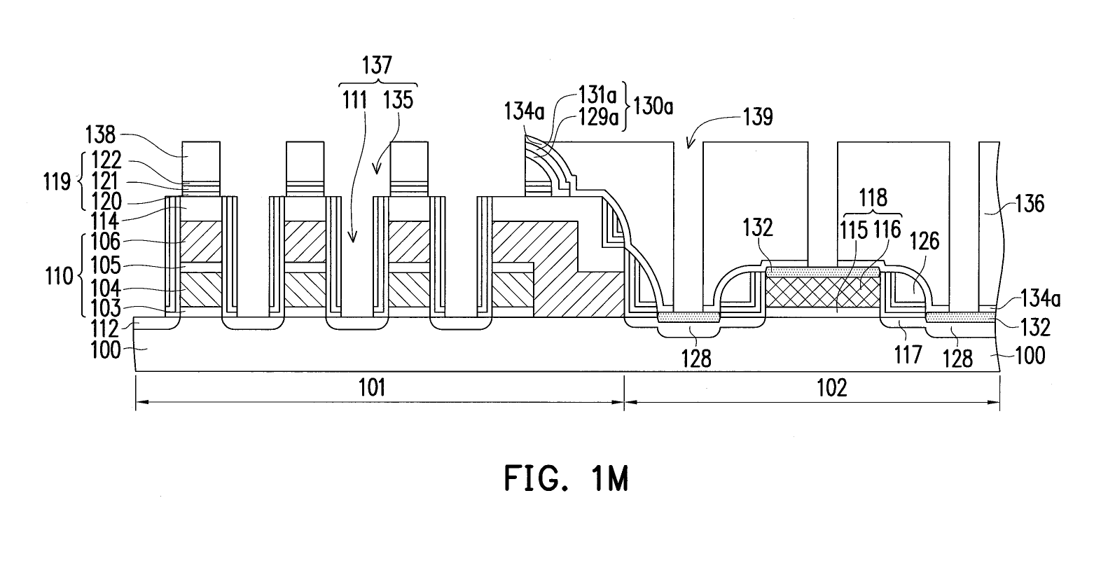

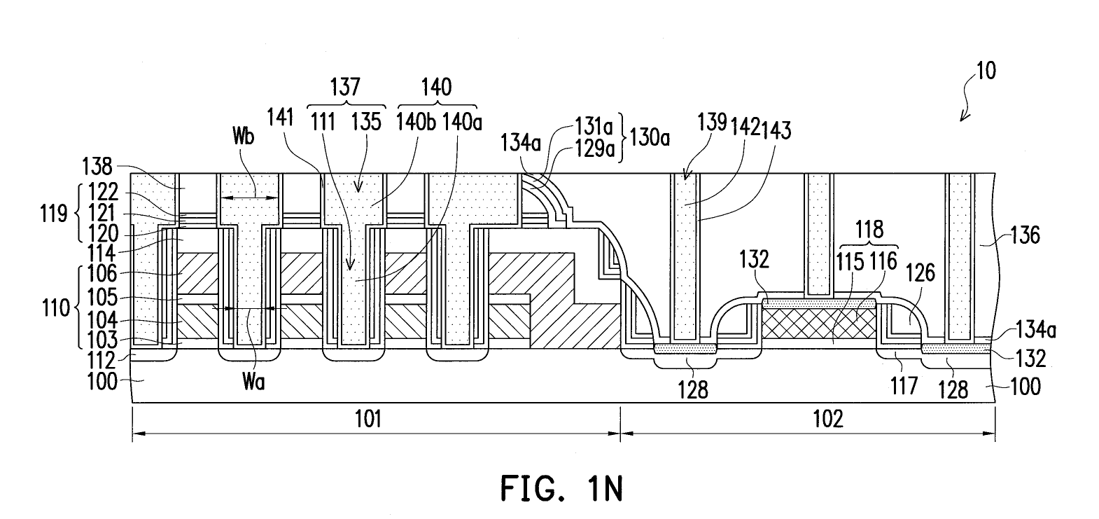

FIG. 1A to FIG. 1N are cross-sectional views illustrating the process of a method of fabricating a semiconductor device according to an embodiment of the invention.

Referring to FIG. 1A, first, a substrate 100 is provided, wherein the substrate 100 has a first region 101 and a second region 102. The substrate 100 can be a silicon substrate. The first region 101 is, for instance, a memory cell region and the second region 102 is, for instance, a peripheral circuit region.

A plurality of stacked gate structures 110 are formed on the substrate 100 of the first region 101, wherein a gap 111 exists between two adjacent stacked gate structures 110. A plurality of doped regions 112 are formed in the substrate 100 of the first region 101, wherein each doped region 112 is located between two adjacent stacked gate structures 110. A gate dielectric material layer 107 and a conductive material layer 108 are formed on the substrate 100 of the second region 102. Moreover, a hard mask layer 113 is formed on the substrate 100, wherein a portion of the hard mask layer 113 is located on the stacked gate structures 110 and another portion of the hard mask layer 113 is located on the conductive material layer 108.

The stacked gate structures 110 can be gate structures of a non-volatile memory device, such as gate structures of a flash memory device. In the present embodiment, each stacked gate structure 110 includes a tunneling dielectric layer 103, a conductive layer 104, a blocking dielectric layer 105, and a conductive layer 106 stacked on the substrate 100 in order. The material of the tunneling dielectric layer 103 is, for instance, silicon oxide. The conductive layer 104 can be used as a charge storage layer, and the charge storage layer can be a floating gate or a charge trapping layer. In the case that the charge storage layer is a floating gate, the material thereof is, for instance, doped polysilicon; and in the case that the charge storage layer is a charge trapping layer, the material thereof is, for instance, silicon nitride. The blocking dielectric layer 105 is, for instance, a multilayer structure of a silicon oxide layer/a silicon nitride layer/a silicon oxide layer (ONO). In the case that the charge storage layer is a floating gate, the blocking dielectric layer 105 can be used as an inter-gate dielectric layer. The conductive layer 106 can be used as a control gate, and the material thereof is, for instance, doped polysilicon. The material of the gate dielectric material layer 107 is, for instance, silicon oxide. The material of the conductive material layer 108 is, for instance, doped polysilicon. The material of the hard mask layer 113 is, for instance, silicon oxide or silicon nitride.

The method of forming the stacked gate structures 110, the gate dielectric material layer 107, and the conductive material layer 108 includes, for instance, sequentially performing a deposition process and a patterning process on the substrate 100 of the first region 101 and the second region 102. The method of forming the doped regions 112 includes, for instance, performing an ion implantation process by using the hard mask layer 113 and the stacked gate structures 110 as a mask.

It should be mentioned that, the conductive layer 106 in the first region 101 and the conductive material layer 108 in the second region 102 are formed by the same material layer. Therefore, after the patterning process is performed, the conductive layer 106 (shown by border A) of the stacked gate structures 110 located at the junction of the first region 101 and the second region 102 has a stepped shape. In other words, the conductive layer 106 (shown by border A) is extended toward the second region 102 and is in contact with the substrate 100.

Referring to FIG. 1B, next, the hard mask layer 113 in the second region 102 is removed to form a hard mask layer 114 located only in the first region 101. The method of removing the hard mask layer 113 in the second region 102 includes the following steps. First, a patterned photoresist layer (not shown) is formed on the substrate 100. Then, a dry etching process is performed by using the patterned photoresist layer as a mask to remove the hard mask layer 113 not covered by the patterned photoresist layer. Then, the patterned photoresist layer is removed.

Referring to FIG. 1C, next, a portion of each of the gate dielectric material layer 107 and the conductive material layer 108 is removed to form a gate structure 118 including a gate dielectric layer 115 and a conductive layer 116 stacked in order on the substrate 100 of the second region 102. The gate structure 118 can be a gate structure of a complementary metal oxide semiconductor (CMOS) device. The material of the gate dielectric layer 115 is, for instance, silicon oxide. The conductive layer 116 can be used as a gate, and the material thereof is, for instance, doped polysilicon. The method of removing the portion of each of the gate dielectric material layer 107 and the conductive material layer 108 includes the following steps. First, a patterned photoresist layer (not shown) is formed on the substrate 100. Then, a dry etching process is performed by using the patterned photoresist layer as a mask to remove the gate dielectric material layer 107 and the conductive material layer 108 not covered by the patterned photoresist layer. Then, the patterned photoresist layer is removed.

In FIG. 1C, one gate structure 118 is formed on the substrate 100 of the second region 102 as an example, but the invention is not limited thereto. In other embodiments, a plurality of gate structures 118 can be formed on the substrate 100 of the second region 102.

Then, after the gate structure 118 is formed, an ion implantation step is performed to form a plurality of shallow doped regions 117 in the substrate 100 on both sides of the gate structure 118.

Referring to FIG. 1D, next, a liner layer 119 is conformally formed on the substrate 100 to cover the stacked gate structures 110 and the gate structure 118. In the present embodiment, the liner layer 119 is, for instance, a multilayer structure of a silicon oxide layer 120/a silicon nitride layer 121/a silicon oxide layer 122 (ONO), and the method of forming the liner layer 119 includes depositing the silicon oxide layer 120, the silicon nitride layer 121, and the silicon oxide layer 122 on the substrate 100 in order with a chemical vapor deposition (CVD) method. Moreover, the liner layer 119 has a high etch selection ratio toward a sacrificial layer 124.

Then, the sacrificial layer 124 filling the gap 111 is formed in the first region 101. The material of the sacrificial layer 124 is, for instance, polysilicon. The method of forming the sacrificial layer 124 includes the following steps. First, a sacrificial material layer (not shown) is conformally formed on the substrate 100. Then, a patterned photoresist layer (not shown) is formed on the sacrificial material layer. Then, a dry etching process is performed by using the patterned photoresist layer as a mask to remove the sacrificial material layer not covered by the patterned photoresist layer. Then, the patterned photoresist layer is removed. Specifically, since the liner layer 119 has a high etch selection ratio toward the sacrificial layer 124, when the dry etching process is performed to remove the sacrificial material layer not covered by the patterned photoresist layer, the sacrificial material layer in the second region 102 can be effectively removed.

Referring to FIG. 1E, a dielectric layer 125 covering the liner layer 119 is conformally formed on the substrate 100. The material of the dielectric layer 125 is, for instance, silicon oxide, and the method of forming the dielectric layer 125 is, for instance, a CVD method.

Referring to FIG. 1F, then, a portion of each of the dielectric layer 125 and the liner layer 119 is removed to form a spacer 126 and a plurality of openings 127 on the substrate 100, wherein the openings 127 expose the substrate 100 on both sides of the gate structure 118. Specifically, the method of forming the spacer 126 and the openings 127 includes the following steps. First, an etch-back is performed to remove the portion of the dielectric layer 125 to form the spacer 126 on the sidewall of the gate structure 118. Then, using the spacer 126 as a mask, the portion of the liner layer 119 is removed to expose the top portion of the gate structure 118 and form the openings 127 exposing the substrate 100 on both sides of the gate structure 118. Moreover, in the step of forming the spacer 126, a spacer structure can be formed in the regions shown by borders B1, B2, and B3 at the same time.

Then, using the spacer 126 as a mask again, an ion implantation step is performed to form a plurality of doped regions 128 in the exposed substrate 100 in the openings 127. Moreover, in the step of forming the doped regions 128, an ion implantation step can be performed on the gates (i.e., the conductive layer 116) of the exposed gate structure 118.

Referring to FIG. 1G, then, a dielectric layer 130 covering the sacrificial layer 124 is formed in the first region 101. In the present embodiment, the dielectric layer 130 is, for instance, a composite dielectric layer of an oxide layer 129 and a nitride layer 131, wherein the oxide layer 129 is located on the sacrificial layer 124 and the nitride layer 131 is located on the oxide layer 129. The material of the oxide layer 129 is, for instance, silicon oxide, and the material of the nitride layer 131 is, for instance, silicon nitride. The method of forming the dielectric layer 130 includes the following steps. First, an oxide material layer (not shown) and a nitride material layer (not shown) are deposited on the sacrificial layer 124 in order with a CVD method. Then, a patterned photoresist layer (not shown) is formed on the nitride material layer. Next, a dry etching process is performed by using the patterned photoresist layer as a mask and the oxide material layer as a stop layer to remove the nitride material layer not covered by the patterned photoresist layer to form the nitride layer 131. Then, the patterned photoresist layer is removed. Lastly, a wet etching process is performed to remove the oxide material layer not covered by the nitride layer 131 to form the oxide layer 129. In the wet etching process, a hydrofluoric acid solution can be used as an etchant.

Moreover, since the anti-etch characteristics of the nitride layer 131 in the wet etching process is higher than the anti-etch characteristics of the nitride layer 129 in the wet etching process, a wet etching process can be used to remove the oxide material layer not covered by the nitride layer 131. Moreover, in the present embodiment, the dielectric layer 130 can be used as a self-aligned salicide block layer (SAB) or used as a film layer of resistive protection oxide layer (RPO).

Referring to FIG. 1H, then, a metal silicide layer 132 is formed on the top portion of the gate structure 118 and the exposed substrate 100 in the openings 127 to reduce the resistance of the device and increase conductivity. The material of the metal silicide layer 132 is, for instance, titanium silicide, cobalt silicide, nickel silicide, palladium silicide, platinum silicide, or molybdenum silicide. The method of forming the metal silicide layer 132 is, for instance, a self-aligned salicide process. Specifically, since the hard mask layer 113 in the second region 102 is removed (FIG. 1B) and the dielectric layer 130 used as a SAB or an RPO is formed on the sacrificial layer 124, the metal silicide layer 132 can be formed only on the exposed substrate 100 in the openings 127 and on the conductive layer 116 of the gate structure 118. In other words, since the dielectric layer 130 covers the sacrificial layer 124, the metal silicide layer 132 is not formed in the first region 101 so as to prevent forming a metal salicide on the sacrificial layer 124 for which the material is polysilicon. As a result, the issue of etching interference in a subsequent process is prevented.

Referring to FIG. 1I, then, an etch stop layer 134 is conformally formed on the substrate 100. The material of the etch stop layer 134 is, for instance, silicon nitride, and the method of forming the etch stop layer 134 is, for instance, a CVD method. In the present embodiment, the etch stop layer 134 covers the gate structure 118 and the spacer 126 in the second region 102, and covers the sacrificial layer 124 in the first region 101 at the same time.

Then, an interlayer dielectric layer (ILD) 136 is formed on the substrate 100 to at least cover the etch stop layer 134 in the second region 102. The material of the interlayer dielectric layer 136 is, for instance, silicon oxide. The method of forming the interlayer dielectric layer 136 includes the following steps. First, a dielectric material layer (not shown) completely covering the first region 101 and the second region 102 is formed on the substrate 100. Then, using the etch stop layer 134 in the first region 101 as a stop layer, a planarization process is performed on the dielectric material layer to obtain the interlayer dielectric layer 136, wherein the top surface of the interlayer dielectric layer 136 and the top surface of the etch stop layer 134 are substantially located on the same plane. The planarization process is, for instance, a chemical mechanical polishing process.

Referring to FIG. 1J, then, a portion of the etch stop layer 134, a portion of the dielectric layer 130, and a portion of the sacrificial layer 124 are removed to form, on the substrate 100, a patterned etch stop layer 134a, a patterned dielectric layer 130a (i.e., a composite dielectric layer including an oxide layer 129a and a nitride layer 131a), a patterned sacrificial layer 124a, and a plurality of openings 133 exposing the liner layer 119 above the stacked gate structures 110. The method of removing the portion of each of the etch stop layer 134, the dielectric layer 130, and the sacrificial layer 124 includes the following steps. First, a patterned photoresist layer (not shown) is formed on the substrate 100. Then, a dry etching process is performed by using the patterned photoresist layer as a mask to remove the etch stop layer 134, the dielectric layer 130, and the sacrificial layer 124 not covered by the patterned photoresist layer. Then, the patterned photoresist layer is removed.

Moreover, in the present embodiment, when the patterned etch stop layer 134a, the patterned dielectric layer 130a, the patterned sacrificial layer 124a, and the openings 133 are formed, since the liner layer 119 has a high etch selection ratio toward the sacrificial layer 124, better etching conditions can be used to remove the portion of the sacrificial layer 124 to obtain openings 133 having good vertical profile.

Referring to FIG. 1K, next, a plurality of isolation layers 138 filling the openings 133 are formed in the openings 133. The material of the isolation layers 138 is, for instance, silicon oxide. The method of forming the isolation layers 138 includes the following steps. First, an isolation material layer (not shown) completely covering the first region 101 and the second region 102 is formed on the substrate 100. Then, using the etch stop layer 134a in the first region 101 as a stop layer, a planarization process is performed on the isolation material layer to obtain the isolation layers 138.

Moreover, since the patterned etch stop layer 134a, the patterned dielectric layer 130a, and the patterned sacrificial layer 124a correspond to the locations of contact holes to be formed in a subsequent process, the isolation layers 138 can be used to isolate each contact hole and can be used as a mask layer defining the contact holes in a subsequent process.

Referring to FIG. 1L, then, a portion of the patterned etch stop layer 134a, a portion of the patterned dielectric layer 130a, the patterned sacrificial layer 124a, and a portion of the liner layer 119 are removed to form a plurality of contact holes 137 exposing the doped regions 112 in the first region 101. The method of forming the contact holes 137 is, for instance, a SAC process. Specifically, the method of forming the contact holes 137 includes performing a dry etching process on the patterned etch stop layer 134a, the patterned dielectric layer 130a, the patterned sacrificial layer 124a, and the liner layer 119 by using the isolation layers 138 and the interlayer dielectric layer 136 as a mask to remove the portion of the patterned etch stop layer 134a, the portion of the patterned dielectric layer 130a, the patterned sacrificial layer 124a, and the portion of the liner layer 119.

Moreover, in the present embodiment, the portion of the liner layer 119 which is removed includes the liner layer 119 located on the doped regions 112 and the liner layer 119 located above the stacked gate structures 110 and not covered by the isolation layers 138. Therefore, in the first region 101, a portion of the liner layer 119 is located on the sidewall of each stacked gate structure 110, and another portion of the liner layer 119 is located above the stacked gate structures 110. However, the invention is not limited thereto. In other embodiments, the isolation layers 138 may completely cover the liner layer 119 located above the stacked gate structures 110, and therefore the liner layer 119 located above the stacked gate structures 110 is not removed.

Moreover, after the portion of the patterned etch stop layer 134a, the portion of the patterned dielectric layer 130a, the patterned sacrificial layer 124a, and the portion of the liner layer 119 are removed, a hole 135 is formed between two adjacent isolation layers 138, and the gap 111 and the hole 135 between two adjacent liner layers 119 form a contact hole 137.

Moreover, since the liner layer 119 has a high etch selection ratio toward the patterned sacrificial layer 124a, better etching conditions can be used to remove the patterned sacrificial layer 124a to obtain contact holes 137 having good vertical profile. Therefore, when the patterned sacrificial layer 124a is removed to form the contact holes 137, even in the case of an alignment error, the liner layer 119 located on the sidewall of each stacked gate structure 110 can prevent damage to the stacked gate structures 110.

Referring to FIG. 1M, then, a portion of the interlayer dielectric layer 136 and a portion of the patterned etch stop layer 134a are removed to form a plurality of contact holes 139 in the second region 102, wherein the contact holes 139 expose the metal silicide layer 132. The method of removing the portion of the interlayer dielectric layer 136 and the portion of the patterned etch stop layer 134a is, for instance, a dry etching process. The patterned etch stop layer 134a can prevent damage to the gate structure 118 when the contact holes 139 are formed. The reason is, if the patterned etch stop layer 134a covering the gate structure 118 is not formed on the substrate 100 of the second region 102, then the contact holes 139 above the gate structure 118 expose the metal silicide layer 132 located on the gate structure 118 before the contact holes 139 expose the metal silicide layer 132 located on both sides of the gate structure 118. At this point, if the etching process is performed further to expose the metal silicide layer 132 located on both sides of the gate structure 118, then damage occurs to the gate structure 118.

However, in the present embodiment, since the patterned etch stop layer 134a completely covers the substrate 100 of the second region 102, a dry etching process can first be performed on the interlayer dielectric layer 136 by using the patterned etch stop layer 134a as a stop layer, and then performing etching on the patterned etch stop layer 134a to form the contact holes 139.

Referring to FIG. 1N, next, a barrier layer 141 is further formed on the surface of the contact holes 137 and a barrier layer 143 is further formed on the surface of the contact holes 139. The barrier layer 141 and the barrier layer 143 can be formed at the same time, and the material of each of the barrier layer 141 and the barrier layer 143 is, for instance, titanium/titanium nitride (Ti/TiN), tungsten nitride, tantalum, or tantalum nitride. Then, a plurality of contacts 140 and a plurality of contacts 142 are respectively formed in the contact holes 137 and the contact holes 139, wherein the contacts 140 are in contact with the doped regions 112 and the contacts 142 are in contact with the metal silicide layer 132. The contact holes 137 and the contact holes 139 can be formed at the same time, and the material of each of the contacts 140 and the contacts 142 is, for instance, tungsten, copper, aluminum, or other suitable metals. The method of forming the barrier layer 141, the barrier layer 143, the contacts 140, and the contacts 142 can include the following steps. First, a barrier material layer (not shown) is conformally formed on the substrate 100, and the method of forming the barrier material layer is, for instance, a CVD method. Then, a conductive material layer (not shown) is formed on the barrier material layer, and the method of forming the conductive material layer is, for instance, a CVD method. Then, the barrier material layer and the conductive material layer outside the contact holes 137 and the contact holes 139 are removed to form the barrier layer 141, the barrier layer 143, the contacts 140, and the contacts 142 in the contact holes 137 and the contact holes 139. The method of removing the barrier material layer and the conductive material layer located outside the contact holes 137 and the contact holes 139 is, for instance, a chemical mechanical polishing method.

Moreover, in the present embodiment, the contacts 140 include a first portion 140a located in the gaps 111 and a second portion 140b located in the holes 135, and the width Wb of the second portion 140b is greater than the width Wa of the first portion 140a. However, the invention is not limited thereto. In other embodiments, the width Wb of the second portion 140b can be controlled by adjusting the size of the isolation layers 138.

Moreover, in the present embodiment, since the liner layer 119 has a high etch selection ratio toward the patterned sacrificial layer 124a, the liner layer 119 on the sidewall of each stacked gate structure 110 can maintain an intact structure. In this way, the liner layer 119 on the sidewall of each stacked gate structure 110 can prevent the issue of leakage current between the conductive layer 104 of each stacked gate structure 110 and the contacts 140, and provide good electric insulation to the stacked gate structures 110.

Based on the embodiments above, it can be known that the method of fabricating a semiconductor device provided by the invention can integrate a SAC process and a self-aligned metal silicide process such that when a contact is formed in the first region, a metal silicide layer can also be formed in the second region.

Moreover, the semiconductor device 10 provided by the invention can be completed through the embodiments above. Then, in the following, the structure of the semiconductor device 10 provided by an embodiment of the invention is described with reference to FIG. 1N.

First, referring further to FIG. 1N, the semiconductor device 10 includes a substrate 100, a plurality of stacked gate structures 110, a liner layer 119, a plurality of contacts 140, at least one gate structure 118, and a plurality of contacts 142. The substrate 100 has a first region 101 and a second region 102. The stacked gate structures 110 are disposed on the substrate 100 of the first region 101 and a gap 111 exists between two adjacent stacked gate structures 110. Each stacked gate structure 110 includes a tunneling dielectric layer 103, a conductive layer 104, a blocking dielectric layer 105, and a conductive layer 106. In an embodiment, the conductive layer 104 is used as a charge storage layer, and the charge storage layer can be a floating gate or a charge trapping layer. In an embodiment, in the case that the charge storage layer is a floating gate, the blocking dielectric layer 105 can be used as an inter-gate dielectric layer. In an embodiment, the conductive layer 106 is used as a control gate. The liner layer 119 is disposed on the sidewall of each stacked gate structure 110. The contacts 140 are disposed in the gaps 111. The gate structure 118 is disposed on the substrate 100 of the second region 102. The contacts 142 are connected to the top portion of the gate structure 118 and the substrate 100 on both sides of the gate structure 118.

Moreover, in the semiconductor device 10, a metal silicide layer 132 is further included on the top portion of the gate structure 118 and on the substrate 100 on both sides of the gate structure 118. The liner layer 119 further includes a multilayer structure of a silicon oxide layer 120/a silicon nitride layer 121/a silicon oxide layer 122. Moreover, the semiconductor device 10 further includes an isolation layer 138 disposed on the stacked gate structures 110 and a hole 135 exists between two adjacent isolation layers 138. The semiconductor device 10 further includes a barrier layer 141 disposed on the surface of contact holes 137. The semiconductor device 10 further includes an interlayer dielectric layer 136 disposed on the substrate 100 of the second region 102 and covering the gate structure 118. The interlayer dielectric layer 136 has contact holes 139 therein. The semiconductor device 10 further includes a barrier layer 143 disposed on the surface of the contact holes 139. The semiconductor device 10 further includes a hard mask layer 114 disposed on the conductive layer 106 of each of the stacked gate structures 110. Moreover, the material, the forming method, and the efficacy of each member in the semiconductor device 10 are described in detail in the embodiments above and are not repeated herein.

Based on the above, the method of fabricating a semiconductor device provided by the embodiments above can integrate a SAC process and a self-aligned metal silicide process to fabricate a semiconductor device having a contact in the first region and having a metal silicide layer in the second region. Moreover, when the semiconductor device has a metal silicide layer, the metal silicide layer can reduce the resistance of the device and increase conductivity. Moreover, when the liner layer is a multilayer structure of a silicon oxide layer/a silicon nitride layer/a silicon oxide layer, the liner layer on the sidewall of each stacked gate structure can prevent the issue of leakage current between a floating gate and a contact, and can provide good electric insulation to the stacked gate structures to ensure the quality of the semiconductor device.

Although the invention has been described with reference to the above embodiments, it will be apparent to one of the ordinary skill in the art that modifications to the described embodiments may be made without departing from the spirit of the invention. Accordingly, the scope of the invention is defined by the attached claims not by the above detailed descriptions.

What is claimed is:

1. A method of fabricating a semiconductor device, comprising:
providing a substrate, having a first region and a second region, wherein a plurality of stacked gate structures are formed on the substrate of the first region, each stacked gate structure comprises a tunneling dielectric layer, a charge storage layer, an inter-gate dielectric layer, and a control gate, a gap exists between two adjacent stacked gate structures, and at least one gate structure is formed on the substrate of the second region;
conformally forming a liner layer on the substrate;
forming a first dielectric layer covering the liner layer in the second region;
forming a metal silicide layer on a top portion of the gate structure and on the substrate on both sides of the gate structure; and
performing a contact process to form a plurality of contacts connected to the metal silicide layer.

2. The method of claim 1, wherein the liner layer comprises a multilayer structure of a silicon oxide layer/a silicon nitride layer/a silicon oxide layer (ONO).

3. The method of claim 1, further comprising, before the first dielectric layer covering the liner layer is formed in the second region and after the liner layer is conformally formed on the substrate:
forming a sacrificial layer completely filling the gap in the first region.

4. The method of claim 3, further comprising, before the metal silicide layer is formed on the top portion of the gate structure and on the substrate on both sides of the gate structure:
removing a portion of each of the first dielectric layer and the liner layer to form a spacer and a plurality of openings on the substrate.

5. The method of claim 4, further comprising, after the spacer and the openings are formed on the substrate:
forming a second dielectric layer covering the sacrificial layer in the first region.

6. The method of claim 5, wherein the second dielectric layer comprises a composite dielectric layer of an oxide layer and a nitride layer.

7. A semiconductor device, comprising:
a substrate, wherein the substrate has a first region and a second region;
a plurality of stacked gate structures disposed on the substrate of the first region, wherein each stacked gate structure comprises a tunneling dielectric layer, a charge storage layer, a blocking dielectric layer, and a control gate, and a gap exists between two adjacent stacked gate structures;
a liner layer disposed on a sidewall of each stacked gate structure;
at least one gate structure disposed on the substrate of the second region;
a metal silicide layer disposed on a top portion of the gate structure and on the substrate on both sides of the gate structure; and
a plurality of contacts connected to the metal silicide layer.

8. The semiconductor device of claim 7, wherein the liner layer comprises a multilayer structure of a silicon oxide layer/a silicon nitride layer/a silicon oxide layer (ONO).

9. The semiconductor device of claim 7, further comprising an interlayer dielectric layer disposed on the substrate of the second region and covering the gate structure, wherein the interlayer dielectric layer has a plurality of first contact holes therein.

10. The semiconductor device of claim 9, further comprising a first barrier layer disposed on a surface of each first contact hole.

11. The semiconductor device of claim 7, further comprising a plurality of isolation layers disposed on the stacked gate structures, wherein a hole exists between two adjacent isolation layers, and the gap and the hole form a second contact hole.

12. The semiconductor device of claim 11, further comprising a second barrier layer disposed on a surface of the second contact hole.

13. The semiconductor device of claim 7, wherein the control gate of each stacked gate structure located at a junction of the first region and the second region has a stepped shape.

14. A semiconductor device, comprising:
a substrate, wherein the substrate has a first region and a second region;
a plurality of first gate structures disposed on the substrate of the first region, wherein each first gate structure comprises a tunneling dielectric layer, a charge storage layer, an inter-gate dielectric layer, and a control gate, and a gap exists between two adjacent first gate structures;
a liner layer disposed on a sidewall of each first gate structure;
at least one second gate structure disposed on the substrate of the second region; and
a plurality of first contacts connected to a top portion of the second gate structure and the substrate on both sides of the second gate structure.

15. The semiconductor device of claim 14, further comprising a metal silicide layer disposed on the top portion of the second gate structure and the substrate on both sides of the second gate structure.

16. The semiconductor device of claim 14, wherein the control gate of the first gate structure located at a junction of the first region and the second region has a stepped shape.

17. The semiconductor device of claim 14, wherein the liner layer comprises a multilayer structure of a silicon oxide layer/a silicon nitride layer/a silicon oxide layer (ONO).

18. The semiconductor device of claim 14, further comprising a second contact disposed in the gap.

19. The semiconductor device of claim 18, further comprising a plurality of isolation layers disposed on the first gate structures, wherein a hole exists between two adjacent isolation layers.

20. The semiconductor device of claim 19, wherein the second contact comprises a first portion located inside the gap and a second portion located inside the hole, and a width of the second portion is greater than a width of the first potion.
